(19) United States
(12) Patent Application Publication
(10) Pub. No.: US 2010/0229908 A1
(43) Pub. Date: Sep. 16, 2010

(54) SOLAR POWER CONVERSION SYSTEM AND METHODS OF USE

(76) Inventors: Brett Van Steenwyk, San Luis Obispo, CA (US); Harold T. Buscher, Los Osos, CA (US)

Correspondence Address: Houston IP Department;JACKSON WALKER L.L.P., 1401 McKinney St., Suite 1900, Houston, TX, 77010, US

(21) Appl. No.: 12/721,335

(22) Filed: Mar. 10, 2010

Related U.S. Application Data
(60) Provisional application No. 61/209,724, filed on Mar. 10, 2009.

(51) Int. Cl. H01L 35/00; H01L 31/00; H01L 31/052

(52) U.S. Cl. 136/206; 136/259; 136/246

(57) ABSTRACT

A solar power conversion system includes a collector that is adapted to collect and focus solar radiation into a concentrated beam of radiation. A spectral splitter is adapted to receive the concentrated radiation beam and separate the concentrated radiation beam into a plurality of radiation sub-bands. A laser is adapted to receive the radiation sub-band and to generate a coherent laser beam corresponding to a frequency band of radiation. A concentrator receives the coherent laser beam and generate a focused beam of radiation and a conversion element receives the focused beam of radiation and converts the focused beam of radiation to an electrical current

### CROSS-REFERENCE TO RELATED APPLICATION

This application claims the benefit of U.S. Provisional Application No. 61/209,724, filed Mar. 10, 2009, entitled “Solar Power Conversion System.”

### BACKGROUND

The present disclosure relates to solar power conversion systems for converting solar radiation into electrical current and more particularly, solar power conversion systems that utilize one or more spectral splitters to separate solar radiation into sub-bands which may then be converted into electrical current.

There has been a constant worldwide search for low-cost, efficient means for converting sunlight to electricity ongoing for many decades. Enough work has been done that it is now technically difficult to improve the efficiency of existing methods by even a few percent.

Typical commercially-deployed non-concentrating, solid-state cells are in the 11% to 13% efficiency range. Typical commercial concentrating cells are in the 15% to 20% efficiency range. Costs of manufacture generally are proportional to efficiency, as more complex semiconductor structures are required to improve efficiency.

Essentially some widely-deployed cells use combinations of rare, and/or toxic elements in their construction. Non-concentrating cells require large surface areas. Several studies show that a severe shortage of these elements will result from increasing cell manufacturing activity. This activity will likely accelerate as fossil fuel supplies are depleted.

Concentrating cells typically use much less of these rare elements. The majority of their collection areas are glass, metal or plastic reflectors or refractors. The “active” light-to-electricity conversion element might be only a few square centimeters in area, receiving a light intensity 30 to 1000 times that of unconcentrated (about 900 W/square meter) sunlight.

A second advantage of using concentrating solar collectors is that the efficiency of the final, small conversion element improves with intensity. This improvement explains why the best deployed concentrating cells are about twice the efficiency of unconcentrating conversion cells.

Production of the concentrating solar collectors needed to obtain high conversion efficiencies requires both focusing optics accurate over large areas over large temperature ranges, and similarly, accurate solar trackers. These components are costly. As one example, for a 1000:1 concentration, all the sunlight falling on a square meter of earth must be focused down to a 3 cm by 3 cm square of a conversion element, and that spot must be kept from moving off the element more than about ½ cm. Finding a conversion method that does not require extreme concentration for good efficiency would substantially reduce system cost.

The solar spectrum is quite broad at the Earth's surface. Its half-power wavelength extends from about 400 to 1100 nm, with a central peak at 550 nm. Even outside this half-power wavelength, there is still substantial power to be collected between 300 nm and 1800 nm. Single-junction solar cells are efficient only over a small portion of this band; the rest is converted to heat, not electricity.

Multi-junction cells can be made to accept a larger fraction of the solar band, but usually not all of it. The stacking of different junctions in a single solar cell induces other loss mechanisms which reduce the efficiency gains from such an approach. Broadband, efficient converters are much harder to make than narrow band ones, and are much more expensive.

There exists a need for commercial solar cells that capture a substantial portion of the solar spectrum. The lack of widely available commercial solar cells that cover the substantial portion of the solar spectrum is believed to be one of the primary loss mechanisms for solar cells.

While some solar-thermal converters do better in this respect, even the solar-thermal converters leave some of the solar spectrum unconverted. Unfortunately, disadvantages of conventional solar-thermal converters include the requirement for many costly additional elements, for example, hot oil to hot water to steam to a turbine to a generator, which greatly increase their cost and reduce their initial efficiency advantage.

Accordingly, some of the problems associated with present concentrator cell technologies include the cost and difficulty of making accurate large-area optics with accurate solar trackers that produce the high concentrations required for high active element efficiency and allow use of small-area, lower-cost conversion elements. Other disadvantages include the cost and difficulty of making broadband active conversion elements that are efficient over the whole solar spectrum.

### SUMMARY

The present disclosure relates to solar power conversion systems for converting solar radiation into electrical current and more particularly, solar power conversion systems that utilize one or more spectral splitters to separate solar radiation into sub-bands which may then be converted into electrical current.

One aspect of a solar power conversion system includes a collector that is adapted to collect and focus solar radiation into a concentrated beam of radiation. A spectral splitter is adapted to receive the concentrated radiation beam and separate the concentrated radiation beam into a plurality of radiation sub-bands. A laser is adapted to receive the radiation sub-band and to generate a coherent laser beam corresponding to a frequency band of radiation. A concentrator receives the coherent laser beam and generate a focused beam of radiation and a conversion element receives the focused beam of radiation and converts the focused beam of radiation to an electrical current.

Another aspect of a method for converting solar power includes a step of collecting solar radiation with a collector wherein the collector is adapted to collect and focus solar radiation into a concentrated beam of radiation and separating the concentrated beam of radiation into radiation sub-bands using a spectral splitter. The method further includes the steps of converting the radiation sub-bands into a coherent laser beam corresponding to a frequency band of radiation and concentrating the coherent laser beam to generate a focused beam of radiation. The focused beam of radiation is converted to an electrical current.

In another embodiment, a solar power conversion system includes a plurality of lasers adapted to receive a sub-band of solar radiation and to generate a coherent laser beam, each coherent laser beam corresponding to a frequency band of radiation. A plurality of concentrators, wherein each concentrator is adapted to receive one of the focused beams of radiation to generate a focused beam of radiation. A plurality of conversion elements, wherein each conversion element is adapted to receive one of the focused beams of radiation wherein the conversion element is adapted to convert the focused beam of radiation to an electrical current.

### BRIEF DESCRIPTION OF THE DRAWINGS

A more complete understanding of the present disclosure and advantages thereof may be acquired by referring to the following description taken in conjunction with the accompanying figures, wherein:

FIG. 1 illustrates a schematic illustration of a solar power conversion system in accordance with one embodiment of a solar power conversion system.

FIG. 2 illustrates three different types of spectral splitters that can be used with the power conversion system of FIG. 1.

While the present disclosure is susceptible to various modifications and alternative forms, specific exemplary embodiments thereof have been shown by way of example in the drawings and are herein described in detail. It should be understood, however, that the description herein of specific embodiments is not intended to limit the disclosure to the particular forms disclosed, but on the contrary, the intention is to cover all modifications, equivalents, and alternatives falling within the spirit and scope of the disclosure as defined by the appended claims.

### DETAILED DESCRIPTION

The present disclosure generally relates to solar power conversion systems for converting solar radiation into electrical current and more particularly, solar power conversion systems that utilize one or more spectral splitters to separate solar radiation into sub-bands which may then be converted into electrical current. Spectral splitting may also be achieved by selective absorption of different frequency bands by a series of different lasing media.

In certain embodiments, solar power conversion systems comprise collectors, lasers, concentrators, and conversion elements for efficiently capturing and converting sunlight into DC electricity. The collectors collect and focus solar radiation and direct the concentrated radiation to one or more spectral splitters for separating the solar radiation into multiple radiation sub-bands. Lasers may then be used to generate a coherent laser beam from each radiation sub-band. Each coherent laser beam is then routed to a conversion element for conversion to an electrical current. Optional concentrators and reflectors may be utilized at various points such as before or after the lasers to optimize the concentration of radiation. Optional reflectors may be employed to further capture radiation not initially captured as explained further below.

By utilizing spectral splitters to separate the solar radiation into constituent radiation sub-bands, the lasers and/or subsequent conversion elements can be optimized for focusing and conversion of a particular radiation sub-band to which the laser and or conversion element is attuned. Advantages of certain embodiments include, but are not limited to, 1) a reduction in the concentration required for efficient conversion to about 40 times; 2) splitting the solar spectrum into radiation sub-bands, each of which can be efficiently absorbed and converted into a narrow-band, coherent laser output wavelength; 3) allowing the use of an efficient, narrowband, laser light-to-electricity conversion elements rather than broadband conversion elements; 4) allowing the final conversion elements to be smaller and have a lower cost, as the output laser beams can be small in area and do not move with errors in sun tracking or concentrator optics. In essence, certain embodiments result in lower cost solar power conversion systems with improved efficiencies of converting sunlight into electricity; and 5) the conversion element may be placed within the laser/resonator cavity itself, which should significantly relax its performance criteria.

To facilitate a better understanding of the present disclosure, the following examples of certain embodiments are given. In no way should the following examples be read to limit, or define, the scope of the disclosure.

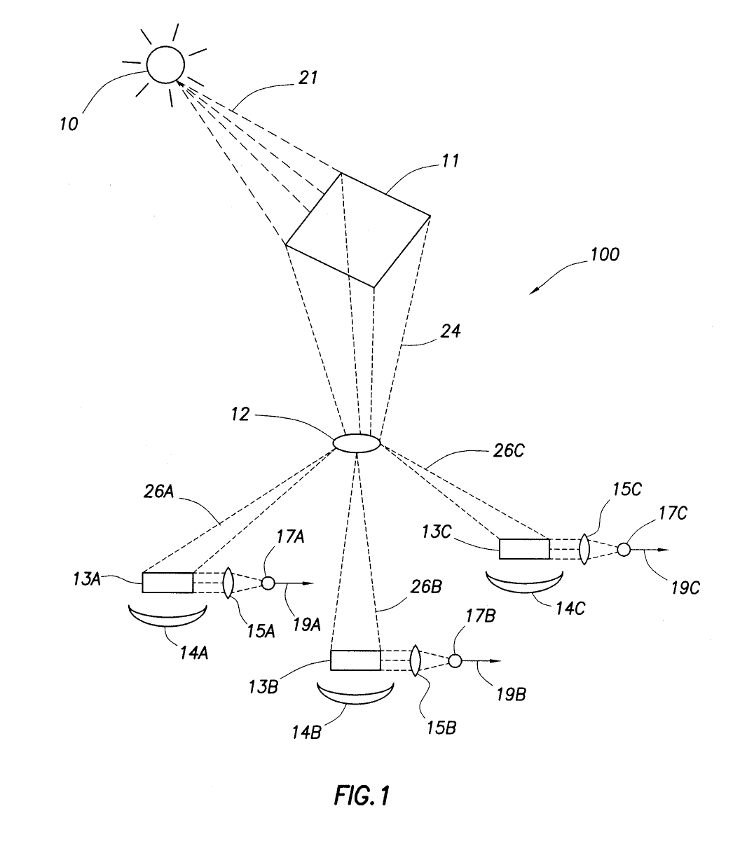

FIG. 1 illustrates a solar radiation 21 that is emitted from the sun 10. A portion of solar radiation 21 is transmitted to a collector 11. The collector 11 is any element having a surface area suitable for conducting the solar radiation 21 to a spectral splitter 12. Examples of suitable collectors for use with the present disclosure include, but are not limited to, lenses, reflectors, mirrors, any optical element suitable for concentrating solar radiation to a spectral splitter, or any combination thereof. In certain embodiments, the collector 11 may comprise multiple elements in series or parallel, such as a parabolic or elliptical reflector used in conjunction with a concentrating lens.

The collector 11 may be a Fresnel lens adapted to collect and focus solar radiation into a concentrated radiation beam 24, which is then received by the spectral splitter 12. In certain embodiments, the concentration of the solar radiation 21 to the concentrated radiation beam 24 may be in the range of about 30 to about 100 times.

The spectral splitter 12 is adapted to receive the concentrated radiation beam 24 and separate the concentrated radiation beam 24 into a plurality of radiation sub-bands 26A, 26B, and 26C. The spectral splitter 12 may be any wavelength band splitter adapted to separate solar radiation into the radiation sub-bands 26A, 26B, and 26C, where each radiation sub-band comprises a different frequency band of the solar radiation spectrum. In one embodiment, spectral splitter 12 may be a stack of fluorescent materials of varying fluorescent frequencies. In certain embodiments, it is recognized that some of the radiation sub-bands may overlap one another.

Although FIG. 1 depicts a spectral splitter which splits concentrated beam of radiation 24 into three separate radiation sub-bands, it is explicitly recognized that spectral splitter 12 may split the concentrated radiation beam 24 into any number of radiation sub-bands, including 2 radiation sub-bands. In certain embodiments, spectral splitter may separate radiation 24 into narrow radiation sub-band half-wavelength ranges of about 100 nm to about 300 nm.

Radiation sub-bands 26A, 26B, and 26C are then routed to lasers 13A, 13B, and 13C. Each laser 13A, 13B, and 13C is adapted to receive one of the radiation sub-bands and to generate a corresponding focused beam of radiation, each focused beam of radiation corresponding to a frequency band of radiation. The term “receive” as used herein refers to receiving at least a portion of the radiation that is directed to the particular element discussed and in no way requires reception or conversion of the entire radiation that is directed to that particular element. Accordingly, the lasers 13A, 13B, and 13C may only receive a portion of the radiation that is directed to each laser 13A, 13B, and 13C.

The term “laser” as used herein refers to any device suitable for converting at least a portion of radiation introduced to it to a coherent beam of radiation and explicitly includes lasers as that term is used in the art. Examples of suitable lasers include, but are not limited to lasers discussed in the papers T. Yabe, et al., “Demonstrated fossil-fuel-free energy cycle using magnesium and laser”, App. Phys. Lett., 89, 261107 (2006) and T. Saiki, et al., “Nd/Cr:YAG Ceramic Rod Laser Pumped Using Arc-Metal-Halide-Lamp”, Jap. J. App. Phys., 46 No. 1, 2007, pp. 156-160, both of which are hereby incorporated by reference. Combinations of these lasers and other lasers known in the art may also be used in conjunction with the present disclosure. In certain embodiments, lasers 26 are optimized to generate narrow-band, coherent laser beams based on the particular radiation sub-band directed to the particular laser 13A, 13B, or 13C. In this way, the lasing medium is optimized to capture as much of the solar spectral energy as possible.

The lasers 13A, 13B, and 13C may incorporate Fabry-Perot minors 15, which allow laser oscillations to produce a narrow output beam that reduces its diameter to that of the conversion elements 17. As mentioned previously, the conversion of solar radiation into a single-wavelength, collimated output beam allows optical tolerances to be relaxed, makes the laser/conversion element assembly immune to minor input beam error motions, reduces the size of the conversion elements, and allows optimizing its efficiency at the laser output wavelength(s).

Optional reflectors 14A, 14B, and 14C capture radiation not captured by the lasers 13A, 13B, and 13C and reflect the radiation back to the lasers 13A, 13B, or 13C. In this way, the reflectors 14A, 14B, and 14C increase the efficiency of solar power conversion system 100. The reflectors 14A, 14B, and 14C may be incorporated at any point in the solar power conversion system 100 to capture radiation not captured in a first pass including, but not limited to, before and/or after the lasers 13A, 13B, and 13C. That is, radiation uncaptured by lasers 13A, 13B, and 13C on the first pass may be refocused into lasers 13A, 13B, and 13C by the reflectors 14A, 14B, and 14C for increased efficiency. The reflectors 14A, 14B, and 14C are particularly suitable where the laser (or lasers) (typically doped glass/ceramic) are rod-shaped and larger than an affordable concentrator's focus spot. In certain embodiments, reflectors 14A, 14B, and 14C may be ellipsoidal reflectors, parabolic mirrors, or any combination thereof. A simple ellipsoidal reflector beneath the rod can refocus the first-pass sunlight back into the rod for increased pumping efficiency. A dual-lens, beam-size transformer telescope on the laser output can adjust its beam diameter to that of a practical conversion element.

Concentrators 15A, 15B, and 15C are adapted to receive one of the focused beams of radiation so as to each generate a focused beam of radiation. The focused beam of radiation is directed to conversion elements 17A, 17B, or 17C. Concentrators that may be used with the power conversion system 100 include any element adapted to concentrate or otherwise focus radiation to a smaller surface area and/or to a greater intensity. Examples of suitable concentrators include, but are not limited to, lenses, optical fiber, solid state concentrators, or any optical elements known in the art for focusing or concentrating radiation or increasing the intensity thereof. Concentrators may be incorporated at any point in the solar power conversion system 100 along a path of radiation including, but not limited to, before or after collector 11, before or after spectral splitter 12, before or after the lasers 13A, 13B, and 13C. In certain embodiments, concentrators 15A, 15B, and 15C are optional.

The conversion elements 17A, 17B, and 17C are adapted to receive one of the coherent laser beams from the lasers 13A, 13B, and 13C wherein the conversion element is adapted to convert the coherent laser beam to electrical current 19A, 19B, and 19C. In certain embodiments, the particular conversion element 17A, 17B, or 17C is optimized for conversion of the particular frequency or wavelength of radiation that is routed to the particular conversion element 17A, 17B, or 17C from one of the lasers 13A, 13B, or 13C.

Conversion elements 17A, 17B, and 17C (also referred to herein as “detectors) may be any device adapted to convert radiation into electricity. Suitable elements include, but are not limited to solar photovoltaic (PV) cells, solar thermal cells, solar thermoelectric cells, multijunction solar PV cells, or any combination thereof. Other suitable examples of conversion elements 17 are available from Photovolt, Inc, 21282 Woodview Cir., Strongsville, Ohio 44149-9261. Even though some of these conversion elements may not be optimized for the 1.06 micron laser output wavelength, but they may still achieve 60% efficiency in certain embodiments. Although not illustrated here, a conversion element may be placed within the laser itself.

In a simpler, but less efficient implementation of solar power conversion system 100, the spectral splitter 12 is omitted, and one or more lasers (each with different absorption bands and output frequencies) with respective converting elements are used with one or more concentrators.

There are numerous useable concentrators commercially available, some as simple as a thin, plastic Fresnel lens. Similarly, there are also solar-optimized laser media (at 43% efficiency) and small, multi-junction detectors (at 60% efficiency) now available. In certain embodiments, neither the laser media nor the detectors may be optimized for specific wavelength bands, but at over 24% cascaded efficiency, they still exceed the efficiency of known commercial concentrator cells.

The power conversion system disclosed herein is able to convert relatively broad sunlight sub-bands into a single laser output wavelength beam and provide increased conversion element efficiency. Similarly, the lasing media can be doped to optimize their absorption of each of the available pump sub-band wavelengths, again much easier than attempting to efficiently absorb the entire solar spectral width.

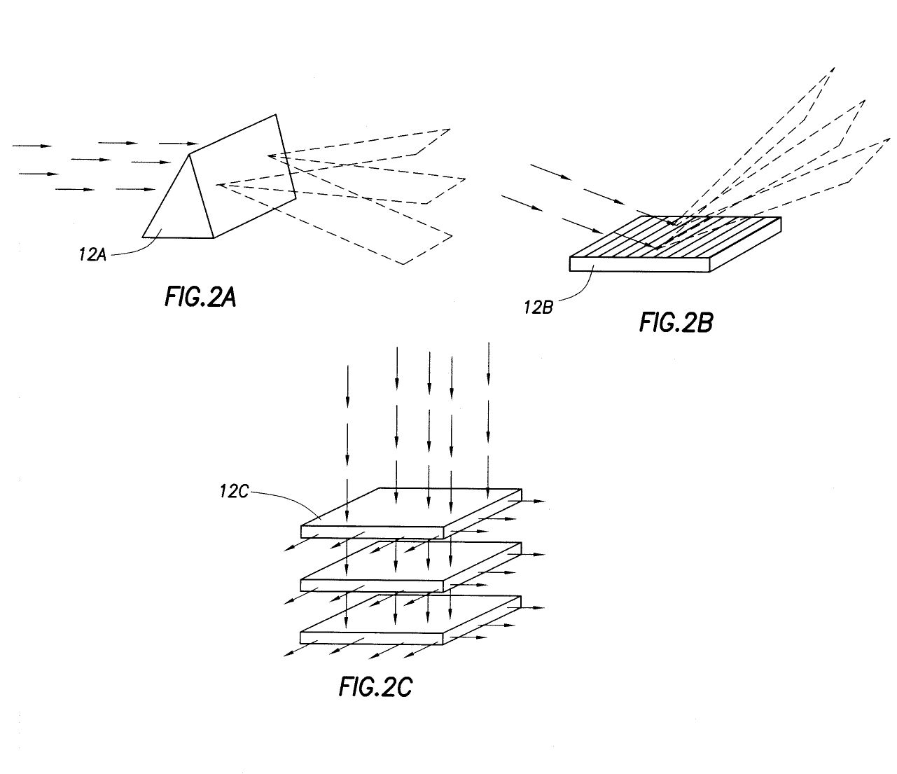

FIG. 2 illustrates three different types of spectral splitters. Types A and B can be placed in the converging beam path above the focal spot, 12, as shown in FIG. 1. One embodiment uses a refractive prism, made of glass, quartz, or any other transparent solid. An example producing three sub-band foci at different wavelengths and spatial positions is shown in FIG. 2A. A more compact diffraction grating splitter that produces three sub-bands is shown in FIG. 2B. Type C splitters can function with less concentration, as they self-concentrate input light by total internal reflection. Such light ends up at the edges of the type C splitters where the laser rods are typically disposed.

The three slabs shown in FIG. 2C are typically dye-loaded plastics. Each contains a different dye that scatters the input beam into the plane of the slab and selectively absorbs a distinct sub-band, converting it to a more narrow fluorescent output band that can be used to pump lasers tuned for that band. Sunlight sub-bands not converted by the first slab pass through it to be captured by subsequent ones.

The square slabs shown might be illuminated by collector 11 of FIG. 1 (e.g. a single converging Fresnel lens) followed by a second collimating Fresnel to produce the 30-100 times concentrated input beam shown in FIG. 2C.

Four laser rods(not shown) could be placed around the edges of each slab, with minors configured to form a ring-laser amplifier, with one output beam directed to an optimized conversion element. In such an embodiment, alignment of the input solar beam is quite uncritical for this system, and the laser rods can be much smaller in diameter. Example of suitable types of plastic concentrator material is described in a paper by M. J. Currie, et al., “High-Efficiency Organic Solar Concentrators for Photovoltaics”, Science 11, July 2008: Vol. 321, No. 5886, pp. 226-8, which is hereby incorporated by reference.

The disclosed power conversion system 100 exceeds the solar-to-electric conversion efficiency of typical commercial flat panel and concentrator solar cell technologies with the spectral splitter, concentrator, and laser intermediary features described herein. Accordingly, solar power conversion systems described herein may also achieve a lower system cost per Watt generated than conventional solar-electric conversion technologies.

It is explicitly recognized that any of the elements and features of each of the devices described herein are capable of use with any of the other devices described herein with no limitation. Furthermore, it is explicitly recognized that the steps of the methods herein may be performed in any order except unless explicitly stated otherwise or inherently required otherwise by the particular method.

Therefore, the present disclosure is well adapted to attain the ends and advantages mentioned as well as those that are inherent therein. The particular embodiments disclosed above are illustrative only, as the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present disclosure. Also, the terms in the claims have their plain, ordinary meaning unless otherwise explicitly and clearly defined by the patentee.

What is claimed is:

1. A solar power conversion system comprising:
a collector adapted to collect and focus solar radiation into a concentrated beam of radiation;
a spectral splitter adapted to receive the concentrated radiation beam and separate the concentrated radiation beam into a plurality of radiation sub-bands;
a laser that is adapted to receive the radiation sub-band and to generate a coherent laser beam corresponding to a frequency band of radiation;
a concentrator adapted to receive the coherent laser beam and generate a focused beam of radiation; and
a conversion element adapted to receive the focused beam of radiation and convert the focused beam of radiation to an electrical current.

2. The solar power conversion system of claim 1 wherein the spectral splitter is adapted to split the concentrated beam of radiation into a plurality of radiation sub-bands.

3. The solar power conversion system of claim 1 wherein the spectral splitter is a solar radiation splitter.

4. The solar power conversion system of claim 1 wherein the spectral splitter is one of a refractive prism, a diffraction grating splitter, a dye-loaded plastic slab splitter.

5. The solar power conversion system of claim 1 wherein the laser is a doped glass laser, a doped ceramic laser, a continuous-wave laser, a pulsed operation laser, a gas laser, a solid-state laser, a fiber-hosted laser, a photonic crystal laser, a semi-conductor laser, a dye laser, or a free electron laser.

6. The solar power conversion system of claim 1 the conversion element comprises a photovoltaic cell.

7. The solar power conversion system of claim 1 wherein the conversion element comprises a thermoelectric conversion device that converts the coherent laser beam into heat energy to generate the electrical current.

8. The solar power conversion system of claim 7 wherein the thermoelectric conversion device utilizes a thermo-electric effect, a Rankine cycle device, or other hot fluid-based generation mechanisms.

9. The solar power conversion system of claim 1 further comprising:
a second spectral splitter that is adapted to receive a second radiation sub-band from the spectral splitter and separate the second radiation sub-band into a plurality of additional radiation sub-bands;
a second laser adapted to receive each additional radiation sub-band to generate an additional coherent laser beam, each additional coherent laser beam corresponding to a frequency band of radiation;
a plurality of concentrators adapted to receive one of the additional coherent laser beams so as to generate an additional focused beam of radiation; and
a plurality of conversion elements adapted to receive one of the additional focused beams of radiation wherein the plurality of conversion elements are adapted to convert the additional focused beam of radiation to an electrical current.

10. The solar power conversion system of claim 1 wherein the concentrator comprises two lenses in series.

11. The solar power conversion system of claim 1 the concentrator comprises a Fresnel lens.

12. The solar power conversion system of claim 1 wherein the conversion element is adapted to convert, when combined, more than about 70% of a half-power wavelength solar radiation spectrum of that extends from about 400 nm to about 1100 nm into DC electrical current.

13. The solar power conversion system of claim 12 wherein the conversion element is adapted to convert, when combined, more than about 85% of a half-power wavelength solar radiation spectrum of that extends from about 400 nm to about 1100 nm into DC electrical current.

14. The solar power conversion system of claim 1 further comprising a reflector for reflecting radiation not captured by a first pass of one of the lasers, wherein the reflector is adapted to reflect the radiation not captured by the laser back into the laser.

15. The solar power conversion system of claim 1 wherein the conversion element is optimized to convert a frequency corresponding to the coherent laser beam received by the conversion element.

16. The solar power conversion system of claim 1 wherein the conversion element and the laser are in one enclosure.

17. A method for converting solar power comprising:
collecting solar radiation with a collector wherein the collector is adapted to collect and focus solar radiation into a concentrated beam of radiation;
separating the concentrated beam of radiation into radiation sub-bands using a spectral splitter;
converting the radiation sub-bands into a coherent laser beam corresponding to a frequency band of radiation;
concentrating the coherent laser beam to generate a focused beam of radiation; and
converting the focused beam of radiation to an electrical current.

18. A solar light to electrical energy converter comprising a solar concentrator powering a laser that drives a detector that converts the laser light to DC electrical current.

19. The converter of claim 18 wherein the concentrator operates based on optical reflection, total internal reflection, refraction, fluorescence, or scattering.

20. The converter of claim 18 that utilizes optical elements, fluorescent media or other frequency conversion means to split the concentrated solar spectrum into separate frequency bands that can then be directed to separate lasers selected to be most efficiently pumped by each band.

21. The converter of claim 18 that utilizes solid state laser media including Nd/glass, Nd/YAG, Nd/Cr:YAG and other media, including ceramics, tailored to be efficiently pumped by the natural solar spectrum or one or more of the bands of claim 20.

22. The converter of claim 18 wherein the laser and detector are integrated into a single assembly, sharing cooling means.

23. The converter of claim 18 wherein the laser and its detector are separated, including the cases where a single laser drives multiple detectors and where multiple lasers drive a single detector.

24. The converter of claim 18 utilizing detectors based on multi-junction cell technologies efficiency-optimized for both the specific laser output frequency and high intensity illumination.

25. The converter of claim 18 utilizing detectors based on any technology that efficiently produces electricity from incident light, whether visible, ultraviolet or infrared.

26. The converter of claim 18 that utilizes thermal effects of the laser output beam to generate electricity, including the thermo-electric effect, Rankine cycle, and other hot fluid-based generation means.

27. The converter of claim 18 wherein the lasing media are not solid state.

28. The converter of claim 18 wherein the lasers are of rod form and other forms selected to optimize pumping by the concentrator used.

29. The converter of claim 18 arranged such that there are many of these included in each solar cell.
convert the focused beam of radiation to an electrical current.

30. A solar power conversion system comprising:
a plurality of lasers adapted to receive a sub-band of solar radiation and to generate a coherent laser beam corresponding to a frequency band of radiation;
a plurality of concentrators to receive one of the focused beams of radiation so as to generate a focused beam of radiation; and
a plurality of conversion elements adapted to receive one of the focused beams of radiation wherein the conversion element is adapted to convert the focused beam of radiation to an electrical current.

31. The solar power conversion system of claim 30 further comprising one or more reflectors adapted to reflect at least a portion of any solar radiation not captured by the lasers towards one or more of the lasers.

32. The solar power conversion system of claim 30 wherein one or more of the conversion elements are situated in a laser resonator cavity of one of the lasers.

33. The solar power conversion system of claim 30 wherein each laser is adapted to receive a different sub-band of solar radiation than the other lasers.
